(19) United States
(12) Patent Application Publication
(10) Pub. No.: US 2025/0379150 A1
(43) Pub. Date: Dec. 11, 2025

(54) LOW-K DIELECTRIC MATERIAL FOR INTERCONNECT STRUCTURES

(71) Applicant: International Business Machines Corporation, Armonk, NY (US)

(72) Inventors: Son Nguyen, Schenectady, NY (US); Daniel Charles Edelstein, White Plains, NY (US); Haojun Zhang, Schenectady, NY (US)

(21) Appl. No.: 18/739,898

(22) Filed: Jun. 11, 2024

(51) Int. Cl. H01L 23/532; H01L 23/522

(52) U.S. Cl. CPC H01L 23/53295; H01L 23/5226; H01L 23/53214; H01L 23/53228

(57) ABSTRACT

A semiconductor structure includes an active device region including one or more active devices and a multi-level interconnect structure including two or more levels of interconnects for the one or more active devices in the active device region, where the multi-level interconnect structure includes a silicon, carbon, nitrogen, oxygen and hydrogen (SiCNOH) dielectric material surrounding interconnects in at least two of the two or more levels of interconnects. The multi-level interconnect structure may have the SiCNOH dielectric material surrounding the interconnects in all of the two or more levels of interconnects.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

A field-effect transistor (FET) is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, except for the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another technique useful for reducing the size of FETs is using stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7nm node and beyond. A general process flow for formation of a nanosheet stack involves removing sacrificial layers, which may be formed of Silicon Germanium (SiGe), between sheets of channel material, which may be formed of Silicon (Si).

### SUMMARY

Embodiments of the invention provide techniques for forming semiconductor structures with multi-level interconnect structures in which interconnects in two or more levels of the multi-level interconnect structures are surrounded by a same low-k dielectric material.

In one embodiment, a semiconductor structure includes an active device region including one or more active devices and a multi-level interconnect structure including two or more levels of interconnects for the one or more active devices in the active device region. A silicon, carbon, nitrogen, oxygen and hydrogen (SiCNOH) dielectric material surrounds the interconnects in at least two of the two or more levels.

In another embodiment, a semiconductor structure includes a front-end-of-line region including one or more active devices and a back-end-of-line region including metal interconnects for the one or more active devices, the metal interconnects being arranged in a hierarchy of two or more levels, a bottommost one of the two or more levels being adjacent the front-end-of-line region. A SiCNOH interlayer dielectric material surrounds the metal interconnects in at least two of the two or more levels

In another embodiment, an integrated circuit includes a semiconductor structure including an active device region including one or more active devices and a multi-level interconnect structure including two or more levels of interconnects for the one or more active devices in the active device region. A SiCNOH dielectric material surrounds the interconnects in at least two of the two or more levels.

### BRIEF DESCRIPTION OF THE DRAWINGS

FIG. 1 depicts a structure including an active device region and a multi-level interconnect structure having a same low-k dielectric material in multiple levels thereof, according to an embodiment of the invention.

FIG. 2 depicts a structure including a front-end-of-line region and a back-end-of-line region with multiple metal interconnect levels using a same low-k interlayer dielectric material, according to an embodiment of the invention.

FIG. 3 depicts a structure including a front-end-of-line region, a back-end-of-line region, and a backside power delivery network, in which multiple metal interconnect levels of the back-end-of-line region and the backside power delivery network utilize a same low-k interlayer dielectric material, according to an embodiment of the invention.

FIG. 4A depicts a multi-level metal interconnect structure which uses the same low-k interlayer dielectric material to surround metal interconnects without barrier layers in each level of the multi-level metal interconnect structure, according to an embodiment of the invention.

FIG. 4B depicts a multi-level metal interconnect structure which uses different interlayer dielectric materials to surround metal interconnects with barrier layers in different levels of the multi-level metal interconnect structure, according to an embodiment of the invention.

FIG. 5 shows an integrated circuit comprising one or more multi-level interconnect structures having a same low-k dielectric material in multiple levels thereof, according to an embodiment of the invention.

### DETAILED DESCRIPTION

Illustrative embodiments of the invention may be described herein in the context of illustrative methods for forming semiconductor structures with multi-level interconnect structures in which interconnects in two or more levels of the multi-level interconnect structures are surrounded by a same low-k dielectric material, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

With continuous scaling, more and more devices (e.g., transistors) are packed into integrated circuit chips (e.g., into one or more 100-millimeter (mm)² chips). To provide desired functionality, the devices must be interconnected through wiring and routing. With an increased number of devices in an integrated circuit, more and more wiring and routing resources are required to precisely connect the integrated circuit as desired for a particular use case. Thus, for example, more and more metal layers may be needed to connect all of the devices in an integrated circuit.

An integrated circuit may be formed using front-end-of-line (FEOL) processing for fabricating devices (e.g., transistors, capacitors, resistors, etc.) on a wafer and back-end-of-line (BEOL) processing for interconnecting such devices on the wafer. More particularly, BEOL processes are typically focused on forming metal interconnects between the different devices of an integrated circuit, whereas the fabrication of the different devices that make up the integrated circuit is typically done during FEOL processing.

In FEOL processing, devices such as complementary metal-oxide-semiconductor (CMOS) field-effect transistors (FET) devices are formed by a series of steps. For example, masking layers (e.g., photolithographic masks) may be used to form patterns on a semiconductor substrate or wafer. Such masking layers may be used to control or define specific regions where material is to be etched or removed, as well as to control or define specific regions where material is to be formed (e.g., through deposition, growth, etc.). In some cases, materials may be blanket deposited, followed by patterning of one or more masking layers to remove previously deposited materials in some areas while leaving the previously deposited material in other areas. A FEOL region of a semiconductor structure is an example of what is more generally referred to as an active device region comprising one or more active devices (e.g., transistors and other logic devices).

In BEOL processing, fabrication of an integrated circuit continues by forming interconnects through one or more layers of wiring and dielectric passivation layers over active devices in a FEOL region formed during the FEOL processing. Interconnections or interconnects may include metallic structures that are formed in multiple levels of interlayer dielectric (ILD) layers for electrically connecting the various devices in the FEOL region. Following FEOL and BEOL processing, a wafer may be separated or divided into multiple integrated circuit chips by dicing or other suitable techniques.

In conventional approaches, multiple levels of ILD layers and passivation layers utilize different materials. Different wiring levels (e.g., M0, M1, etc.) have mixed dielectric materials, such as silicon nitride (SiN), silicon dioxide (SiO₂), fluorine-doped silicon oxide (SiOF), a dielectric comprised of silicon, carbon, oxygen and hydrogen (SiCOH), etc. Hierarchical copper (Cu) damascene wiring levels (e.g., M0, M1, etc.) in conventional structures, for example, typically utilize mixed dielectric materials for the ILD in different wiring levels.

In an interconnect structure with multiple levels of interconnects, the interconnects may be arranged in a hierarchy where the size of the interconnects increases from the bottom levels to the top levels (e.g., relatively smaller metal interconnects are in lower levels of the structure and relatively larger metal interconnects are in upper levels of the structure). In conventional approaches, a low-k dielectric material may be used as the ILD for the bottom levels, where towards the top levels the ILD uses SiO₂. For example, topmost interconnect levels which utilize Cu or aluminum (Al) metal interconnects in conventional structures require the use of SiO2 as the ILD material.

Illustrative embodiments provide for multi-level interconnect structures with multiple levels that utilize a same, novel high performance dielectric material with a low dielectric constant k, where a “low-k” dielectric has a k value less than that of SiO₂ (e.g., < 3.9) and a “high-k” dielectric has a k value greater than that of SiO₂ (e.g., > 3.9). In some embodiments, multi-level interconnect structures (e.g., BEOL interconnect structures) are all integrated with ILD layers formed of the novel high performance low-k dielectric material. Thus, some embodiments provide devices with a transformational “all-level” hierarchical multilayer on-chip interconnect structure, with all wiring levels integrated utilizing the novel high-performance low-k dielectric material. The novel high performance low-k dielectric material may be a low-k dielectric material comprised of silicon (Si), carbon (C), nitrogen (N), oxygen (O) and hydrogen (H) (e.g., SiCNOH). In some embodiments, most or all of the levels of a multi-level interconnect structure are integrated with ILD layers formed of the novel high performance low-k dielectric material (e.g., SiCNOH). The low-k SiCNOH dielectric material may include 20-35 atomic (at.) % Si, >50 at.% C, <10 at.% N (e.g., 3-8 at.% N), <10 at.% O (e.g., 1-8 at.% O), and 10-20 at.% H. More particularly, the low-k SiCNOH dielectric material may have 3-8 at.% N and 1-8 at.% O. In some embodiments, at least a topmost level of the interconnect structure which utilizes Cu or Al metal interconnects utilizes the novel high performance low-k dielectric material (e.g., SiCNOH).

Use of the novel high performance low-k dielectric materials described herein as an ILD material for multiple levels of a multi-level interconnect structure provides a number of advantageous characteristics, including: providing a hermetic seal (e.g., an oxygen (O₂) and Cu or other metal barrier); a low k value (e.g., k ≤ 3.3); a high modulus value (e.g., ≥ 32 gigapascal (GPa)); high adhesion to metals (e.g., Cu) and cap dielectric materials (>4 Joules per square meter (J/m²)) with no graded layer; compressive stress; a low plasma-induced degradation (PID) value (e.g., ≤ 0.15, as compared with a PID value of 1 for SiCOH); and a high thermal conductivity value (e.g., ϴ ≥ 0.66 watts per meter-Kelvin (W/m-K)). Further, the novel high performance low-k dielectric materials described herein are suitable for use as a final passivation layer, where conventional approaches typically utilize combinations of SiO₂ and Si₃N₄ for the final passivation layer. The novel high performance low-k dielectric materials described herein may be integrated with zero or ultrathin (e.g., ≤ 1 nanometer (nm)) metal diffusion barriers (e.g., for metallization levels in a BEOL interconnect structure). The novel high performance low-k dielectric materials described herein may also be utilized for backside power delivery network (BSPDN) wiring levels, though high thermal conductivity and medium modulus may also eventually be needed on the backside as the density, dimension reduction, complexity, and wiring and bonding processes evolve.

In some embodiments, a novel high performance low-k dielectric material (e.g., SiCNOH, porous SiCNOH (pSiCNOH)) may be formed utilizing plasma-enhanced chemical vapor deposition (PECVD) processing, and may be used as an insulating later for different metallization levels (e.g., M0, M1, … M10+) which utilize metals such as Cu, cobalt (Co), ruthenium (Ru), tungsten (W), etc., as well as for a final passivation layer for single- and dual-damascene hierarchically-scaled film thicknesses. Advantageously, use of the novel high performance low-k dielectric materials described herein allows for damascene metal diffusion barrier deposition to be omitted or thinned (e.g., ≤ 1nm) at all wiring levels, for all metals. Reactive-ion etching (RIE) may be used for patterning the novel high-performance low-k dielectric materials described herein (e.g., for formation of metal lines, spaces, pillars, etc. in an interconnect structure, in a memory stack, etc.). The novel high-performance low-k dielectric materials described herein may be used as an ILD for various types of different metals, including but not limited to Cu, a copper-aluminum (CuAl) alloy, Co, Ru, W, molybdenum (Mo), iridium (Ir), rhodium (Rh), etc. Plasma-enhanced atomic layer deposition (PEALD), flowable chemical vapor deposition (FCVD) or PECVD may then be used for depositing the novel high performance low-k dielectric material for gap fill, with optional planarization (e.g., using chemical mechanical planarization (CMP) or other suitable processing). Further, the novel high performance low-k dielectric materials described herein may be used to deposit films at final chip layers (e.g., a final passivation layer), where the novel high performance low-k dielectric materials described herein may be subject to subtractive metallization processing to form terminal metal pads and redistribution layer (RDL) wiring, pillars, controlled collapse chip connections (C4s), etc.

As discussed above, the novel high performance low-k dielectric materials described herein advantageously have a high thermal conductivity, and thus can greatly reduce thermal resistance when used for most (or all) levels of a multi-level interconnect structure (e.g., BEOL interconnect structures, BSPDN, high power CMOS (HP-CMOS) structures, etc.). In addition, the novel high performance low-k dielectric materials described herein are robust and have mechanical, chemical and thermal conductivities which allow for the novel high performance low-k dielectric materials described herein to replace conventional dielectric materials at all wiring levels as well as the final passivation layer of a semiconductor structure, including for the thinnest (e.g., <50nm) and thickest (e.g., >1 micrometer (µm)) wiring and via levels. The novel high performance low-k dielectric materials described herein (e.g., SiCNOH/pSiCNOH) also advantageously have a medium modulus (E ~ 13-18 GPa) and stress (Compressive ~50-80 megapascals (MPa)), which leads to less wafer stress and warpage. Further, the ultra-low PID of the novel high performance low-k dielectric materials described herein, combined with their Cu and O₂ diffusion barrier properties, enables complete scaling (e.g., down to 0) of conventional metal diffusion barriers, to minimize line resistance and resistance-capacitance (RC) at all wiring levels. Further, the novel high performance low-k dielectric materials described herein allow for extending Cu to the farthest CMOS nodes <2nm (e.g., 1.4nm, 1.2nm, 1.0nm, etc.). The novel high performance low-k dielectric materials described herein (e.g., SiCNOH/pSiCNOH) can advantageously be used for metallization levels M0 through Mx, where x=10+ (e.g., with ≤ 18nm pitches), and for passivation layers as a substitute for a silicon oxide/silicon nitride (SiOₓ/SiNₓ) stack or flowable oxide or oxide levels. This can be done with damascene processing, where the novel high performance low-k dielectric material (e.g., SiCNOH/pSiCNOH) is patterned, an optional liner is formed, followed by metal (e.g., Cu) fill, CMP and capping. Damascene processing can also be used with Rh, Co, W or other metallization. RIE metallization followed by gap fill is also an option.

Cu and other metal materials (e.g., Ru, Co, W, Rh, Ir, Mo, etc.) used for wiring in integrated circuit chips can use the novel high performance low-k dielectric materials described herein (e.g., SiCNOH/pSiCNOH) as a substitute for SiN/SiOₓ passivation or flowable oxide/SiOₓ ILDs, as the novel high performance low-k dielectric materials described herein (e.g., SiCNOH/pSiCNOH) provide an excellent barrier to diffusion of Cu, water and oxygen, enabling the structure to be formed with a thinner metal barrier layer, or with no metal barrier layer at all. Further, the novel high performance low-k dielectric materials described herein (e.g., SiCNOH/pSiCNOH) provide a robust high modulus low-k dielectric with excellent diffusion and adhesion between Cu or other metals and insulators, to achieve a high time-dependent dielectric breakdown (TDDB) value for passivation layers (e.g., including nano passivation layers). Further, atomic layer deposition (ALD), PEALD, chemical vapor deposition (CVD) and/or PECVD may be used to form the novel high performance low-k dielectric materials described herein (e.g.,SiCNOH/pSiCNOH) for metal gap fill and Cu or other metal interconnect extendibility. Further, the novel high performance low-k dielectric materials described herein (e.g., SiCNOH/pSiCNOH) provide good thermal conductivity (e.g., comparable to SiCNO or SiCN with ϴ ≥ 0.66W/m-K, versus ϴ between 0.22-0.24W/m-K for SiCOH).

In some embodiments, the novel high performance low-k dielectric material (e.g., SiCNOH/pSiCNOH) is formed using a PECVD, which may be a low temperature plasma CVD process. The PECVD process includes reactants entering the chamber, dissociation of the reactants by electric fields at low temperatures, formation of film precursors, adsorption of precursors, diffusion of the precursors into the substrate, surface reactions, desorption of by-products, and by-product removal. Various Si, C, N, O and H element-based precursors may be used in the PECVD process for forming SiCNOH/pSiCNOH.

Silazanes may be cyclic or linear. Suitable cyclic silazanes include one or more of the following compounds: tetramethylcyclotetrasilazanes, hexamethylcyclotetrasilazanes (HMCTZ), and octamethylcyclotetrasilazanes, or combinations thereof. Some specific examples of cyclic silazanes include 1,2,3,4 tetramethylcyclotetrasilazane, 1,1,3,3 tetramethylcyclotetrasilazane, 1,1,3,3,5,5 hexamethylcyclotetrasilazane, 1,2,3,4,5,6 hexamethylcyclotetrasilazane, 1,1,3,3,5,5,7,7 octamethylcyclotetrasilazen, and 1,2,3,4,5,6,7,8 octamethylcyclotetrasilazane. Suitable linear silazanes include hexamethyldisilazane. Suitable substituted silanes may include bis-diethylamine silane (BDEAS), bis(tertiarybutylamino) silane (BTBAS), and tris(dimethylamino)silane (TDMAS).

A carbon-silane containing precursor may comprise at least one of methylsilane, dimethylsilane, Trimethy silane, tetramethyl silane, ethylsilane and other similar carbon silanes.

An oxygen-based element source may include nitrous oxide (N₂O), O₂, water (H₂O), hydrogen peroxide (H₂O₂), ozone (O₃), dinitrogen dioxide (N₂O₂), etc. In general, less reactive oxygen precursors are preferred for better O element control in the film.

A nitrogen-containing gas like nitrogen (N₂) or a nitrogen precursor may include, ammonia (NH₃), hydrazine (N₂H₄), methyl hydrazine, dimethyldrazine, t-butylhydrazine, phenylhydrazine, other hydrazine derivatives, amines, or a nitrogen plasma source (e.g., N₂, N₂/H₂, NH₃, or N₂H₄ plasmas), 2,2'-azotertbutane, organic or alkyl azides, such as methylazide, ethylazide, trimethylsilylazide ((CH₃)₃SiN₃), and other suitable nitrogen sources. Radical nitrogen compounds can be produced by heat, hot-wires and/or plasma, such as NH₃, N₂, Ν₂H₄. In many examples, the nitrogen-containing gas contains ammonia. The nitrogen-containing gas may have a flow rate within a range from about 10 standard cubic centimeter per minute (sccm) to about 2000sccm, preferably from about 50sccm to about 500sccm. In various examples, the nitrogen-containing gas may have a flow rate of about 100sccm, 500sccm, 1000sccm or 1500sccm.

A carbon containing source may include a hydrocarbon like methane (CH₄), ethylene (C₂H₄), ethyne (C₂H₂), propane (C₃H₈), propene (CH₃CH=CH₂), butylene (C₄H₈), etc., preferably in gas source for better carbon control and incorporation with flow rate in the range of about 10-2000sccm.

As discussed above, the novel high performance low-k dielectric materials described herein (e.g., PECVD-formed low-k dielectric such as SiCNOH/pSiCNOH) provide a strong oxidation and Cu or other metal diffusion barrier, and thus may be used as a bonding dielectric for passivation layers. The novel high performance low-k dielectric materials described herein advantageously have lower PID, are strong mechanically, have better TDDB, enable thinner or no metal liners, and have good uniformity and compressive stress without the need for an adhesion layer. Further Cu-to-Cu metal bonding with the novel high performance low-k dielectric materials described herein will enable better tolerance for Cu-to-Cu or another Cu-to-metal misalignment. The novel high performance low-k dielectric materials described herein (e.g., SiCNOH/pSiCNOH) provide improvements (e.g., based on breakdown voltage (BV), barrier properties, dielectric constant) and may be used as a next-generation passivation dielectric with improved TDDB (e.g., SiCNOH ILD can pass a 21-18nm pitch TDDB requirement). Further, improved TDDB is provided for 48nm pitch Cu, even without a metal liner or barrier (e.g., compared with a liner or barrier thickness of 6nm which is required when using conventional ILD materials).

BEOL processing induced damage in low-k SiCOH dielectrics may result from various processing steps, including NH₃ preclean, RIE/PVD damage, etc. For example, damaged low-k SiCOH regions may have depleted carbon, and absorb small moisture (e.g., H₂O, k=80) readily (e.g., to form more Si-OH) and increase the SiCOH ILD’s effective k significantly (e.g., > 15%). Further, with SiCOH dielectrics there is more O on the top of trenches and thus more RIE damage, and with SiCNOH dielectrics there is significantly less O on top of the trench due to RIE damage, as well as minimal surface and sidewall damage (e.g., as there is minimal carbon drop from the top to the bottom and thus limited damage).

In some embodiments, the novel high performance low-k dielectric materials described herein have a fundamental change in composition with high carbon (e.g., 50-56%) and low oxygen (e.g., < 10%) in the film which reduces PID and increases modulus (E). Further, there is a fundamental change in bonding from SiCOH to SiCNH and SiCNOH dielectrics (e.g., a change from O-Si-O to stronger C-Si-C and Si-N bonding matrix structures, which provides a high modulus and reduced Si-CH₃ bonding in SiCNH/SiCNOH which leads to lower PID). There is less Si-CH3 bonding in SiCNOH than pSiCNOH, and less N-H/O-H bonding in SiCNOH than pSiCNOH/SiCNH. Further, the Si-O bonding is stable with small N₂O variation (e.g., 3-5sccm).

Integrated circuits and other semiconductor structures benefit from improved passivation and ILD layers, with benefits resulting from thinner and more robust films, with lower k and minimal or no diffusion of Cu (or other metals) into the dielectric which can impact reliability. Conventional dielectric materials used for passivation layers include SiOₓ/SiNₓ. These materials, particularly SiOₓ, have minimal Cu diffusion and oxidation barrier properties, with higher k at sub-3nm BEOL nodes. The novel high performance low-k dielectric materials described herein include carbon-rich SiCNOH with low k, high modulus, low PID, good oxidation and Cu diffusion barrier properties (e.g., facilitating its use in interconnect structures which utilize Cu, such as BEOL interconnect structures). Further, the novel high performance low-k dielectric materials described herein can be implemented in place of SiOₓ/SiNₓ passivation layers and are suitable for use in BEOL metal interconnect structures (e.g., with Cu, Ru, Co, W and other metal materials) that utilize damascene or RIE patterning. The novel high performance low-k dielectric materials described herein further advantageously enable Cu-to-Cu bonding and will tolerate normal misalignment and enable larger Cu through-silicon via (TSV) size contact bonding.

In the back side or front side (e.g., for TSV), Cu-to-Cu bonding with different sizes or patterns is desired, where only specific Cu regions are to be contacted and other Cu regions are to be contacted by a dielectric. The novel high performance low-k dielectric materials described herein enable Cu-to-Cu contact between different sizes, lines, pillars or other contacts with a higher tolerance for misalignment without causing Cu diffusion. For example, the SiCNOH dielectric material with C > 50 at. %, N < 10 at. %, and O < 10 at. % will act as a good Cu diffusion barrier, even without a metal liner or barrier layer. SiCNOH and pSiCNOH with specific element composition ranges may also be used (e.g., with Si > 25-35 at. %, C > 50 at. %, N < 10 at. % and O <10 at %, with 0-14% porosity for dense SiCNOH and pSiCNOH with low k (2.5-3.3)). As an ILD, SiCNOH and pSiCNOH have strong Si-C bonding formation, low Si-O bonding formation, and high carbon with low oxygen and nitrogen to form a low k but high modulus material, with low PID as well as Cu diffusion and oxidation barrier properties. SiCNOH and lightly porous SiCNOH may also be used for Cu-to-Cu or Cu-to-metal bonding.

In some embodiments, the novel high performance low-k dielectric materials (e.g., SiCNOH, pSiCNOH) may be used at all ILD levels and as a final passivation layer. Such novel high performance low-k dielectric materials enable sub-3nm BEOL passivation and improved reliability in Cu-to-metal backside/frontside power rail or BSPDN bonding for Cu low-k nano devices with improved reliability. The novel high performance low-k dielectric materials may include Si, C, N and O, with C > 50 at. %, O < 10 at. %, N < 10 at. % and Si in a 25-35 at. % range. The novel high performance low-k dielectric materials may further include H in a 10-20 at. % range. The novel high performance low-k dielectric materials, in some embodiments, are dense and lightly porous (e.g., up to 20% porosity) with a k value in the range of 2.5-3.3. The novel high performance low-k dielectric materials may be formed using CVD, PECVD, ALD, PEALD or FCVD processes. Deposition precursors include, for example: a Carbosilane; an organosilicon; nitrogen, oxygen, and hydrocarbon reactants; etc. The novel high performance low-k dielectric materials have various advantageous properties, including a low k value, a high modulus, low PID, and improved metal diffusion and oxidation barrier characteristics that enable any normal misalignment in Cu-to-Cu (or other Cu-to-metal) back side bonding in interconnect and device fabrication applications for heterogeneously integrated (HI) devices and logic devices. Robust ILD materials are needed for various applications, including scaling to sub-3nm and beyond with Cu bonding integration (e.g., with damascene and subtractive metal interconnect fabrication with robust capacitance reduction), artificial intelligence (AI) applications, etc.

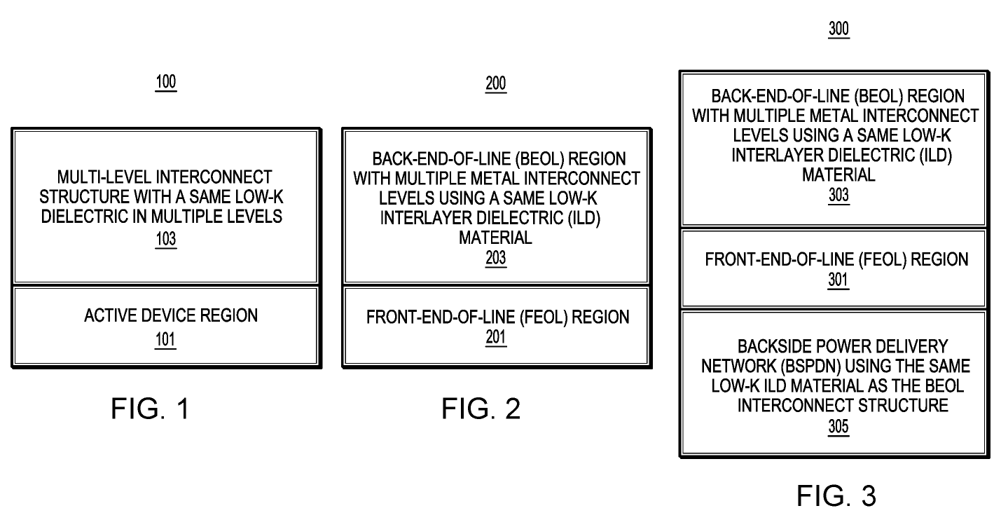

FIG. 1 shows a structure 100 including an active device region 101 including one or more active devices (e.g., transistors or other logic devices) and a multi-level interconnect structure 103 having a same low-k dielectric material (e.g., one of the novel high performance low-k dielectric materials described herein) in multiple levels thereof. The multi-level interconnect structure 103, in some embodiments, includes the same novel high performance low-k dielectric material in most or even all of its multiple levels.

FIG. 2 shows a structure 200 including a FEOL region 201 and a BEOL region 203. The BEOL region 203 has multiple metal interconnect levels (e.g., M1, M2, …, Mx, where x=10+) using a same low-k ILD material, where that low-k ILD material is one of the novel high performance low-k dielectric materials described herein.

FIG. 3 shows a structure 300 also including a FEOL region 301 and a BEOL region 303, as well as a BSPDN 305. The BEOL region 303 has multiple metal interconnect levels (e.g., M1, M2, …, Mx, where x=10+) using a same low-k ILD material, where that low-k ILD material is one of the novel high performance low-k dielectric materials described herein. The BSPDN 305 uses the same ILD material as the multiple metal interconnect levels of the BEOL region 303 (e.g., one of the novel high performance low-k dielectric materials described herein).

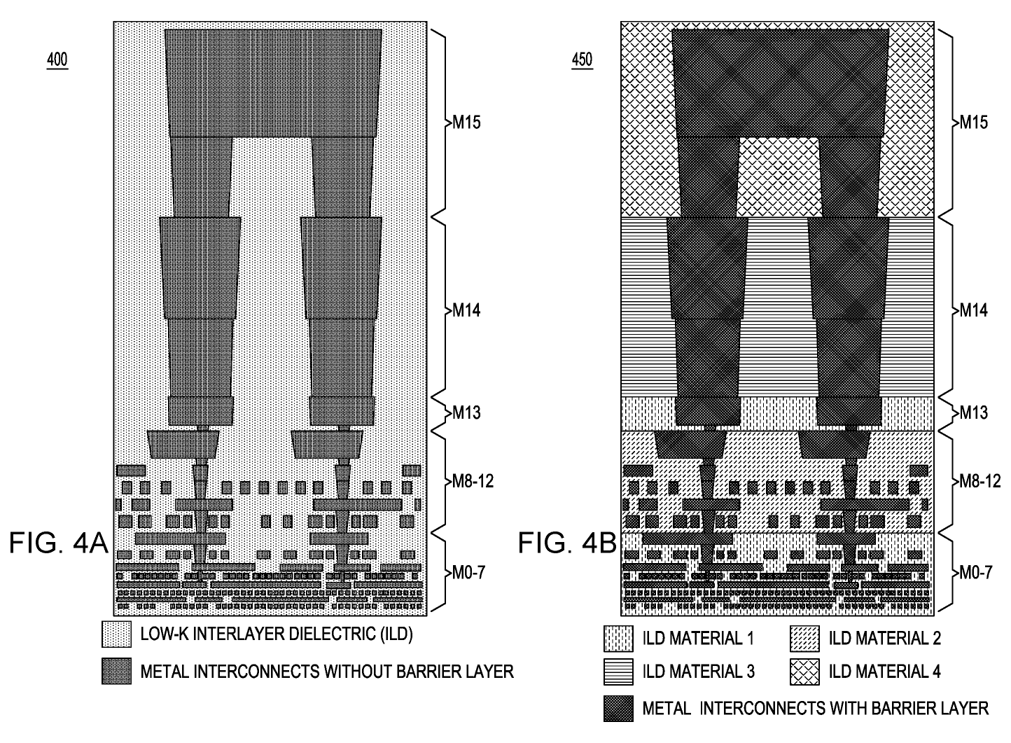

FIG. 4A shows a multi-level interconnect structure 400, including metal interconnects in multiple levels M0-M15, where a same low-k ILD (e.g., one of the novel high performance low-k dielectric materials described herein) surrounds the metal interconnects in each of the levels M0-M15, and where there are no barrier layers between the metal interconnects and the low-k ILD. FIG. 4B shows another multi-level interconnect structure 450, which similarly includes metal interconnects in multiple levels M0-M15. The multi-level interconnect structure 450, however, includes different ILD materials surrounding the metal interconnects in different ones or groups of the levels M0-M15 (e.g., a first ILD material surrounding the metal interconnects in levels M0-M7 and M13, a second ILD material surrounding the metal interconnects in levels M8-M12, a third ILD material surrounding the metal interconnects in level M14, and a fourth ILD material surrounding the metal interconnects in level M15), and where there are ultrathin (e.g., 0.5-3nm) barrier layers between the metal interconnects and the different ILD materials. As described above, the mixed-ILD approach used in the multi-level interconnect structure 450 has various disadvantages relative to the uniform or same ILD approach using one of the novel high performance low-k dielectric materials used in the multi-level interconnect structure 400.

According to an aspect of the invention, a semiconductor structure includes an active device region comprising one or more active devices and a multi-level interconnect structure comprising two or more levels of interconnects for the one or more active devices in the active device region. A SiCNOH dielectric material surrounds the interconnects in at least two of the two or more levels.

In embodiments, the active device region comprises a FEOL region and the multi-level interconnect structure comprises a BEOL region. The semiconductor structure may further include a BSPDN including one or more power rail interconnections surrounded by the SiCNOH dielectric material.

In embodiments, the SiCNOH dielectric material surrounds the interconnects in all of the two or more levels.

In embodiments, the SiCNOH dielectric material provides an oxygen and metal diffusion barrier for the interconnects in the at least two of the two or more levels.

In embodiments, a dielectric constant value of the SiCNOH dielectric material is less than or equal to 3.3.

In embodiments, the interconnects in the at least two of the two or more levels are Cu or Al.

In embodiments, the SiCNOH dielectric material is a porous SiCNOH dielectric material.

In embodiments, the SiCNOH dielectric material is a porous SiCNOH dielectric material. The SiCNOH dielectric material may have greater than 50 at.% C, less than 10 at.% N and less than 10 at.% O. The SiCNOH dielectric material may have 20-35 at.% Si and 10-20 at.% H. The SiCNOH dielectric material may have 3-8 at.% N and 1-8 at.% O.

According to an aspect of the invention, a semiconductor structure includes a FEOL region including one or more active devices and a BEOL region comprising metal interconnects for the one or more active devices, the metal interconnects being arranged in a hierarchy of two or more levels, a bottommost one of the two or more levels being adjacent the front-end-of-line region. A SiCNOH ILD material surrounding the metal interconnects in at least two of the two or more levels.

In embodiments, the SiCNOH ILD material directly contacts the metal interconnects in the at least two of the two or more levels.

In embodiments, the SiCNOH ILD material surrounds the metal interconnects in all of the two or more levels.

In embodiments, the at least two of the two or more levels include an uppermost one of the two or more levels which utilize Cu or Al for the metal interconnects.

In embodiments, the SiCNOH ILD material has 20-35 at.% Si, greater than 50 at.% C, less than 10 at.% N, less than 10 at.% O and 10-20 at.% H.

According to an aspect of the invention, an integrated circuit includes a semiconductor structure including an active device region including one or more active devices and a multi-level interconnect structure including two or more levels of interconnects for the one or more active devices in the active device region. A SiCNOH dielectric material surrounds the interconnects in at least two of the two or more levels of interconnects.

In embodiments, the SiCNOH dielectric material surrounds the interconnects in all of the two or more levels.

In embodiments, the interconnects in the at least two of the two or more levels comprise Cu or Al.

In embodiments, the SiCNOH ILD material has 20-35 at.% Si, greater than 50 at.% C, less than 10 at.% N, less than 10 at.% O and 10-20 at.% H.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, complementary metal-oxide-semiconductor (CMOS) transistors, metal-oxide-semiconductor field-effect transistors (MOSFETs), and/or FinFETs. By way of non-limiting example, the semiconductor devices can include, but are not limited to CMOS, MOSFET, and FinFET devices, and/or semiconductor devices that use CMOS, MOSFET, and/or FinFET technology.

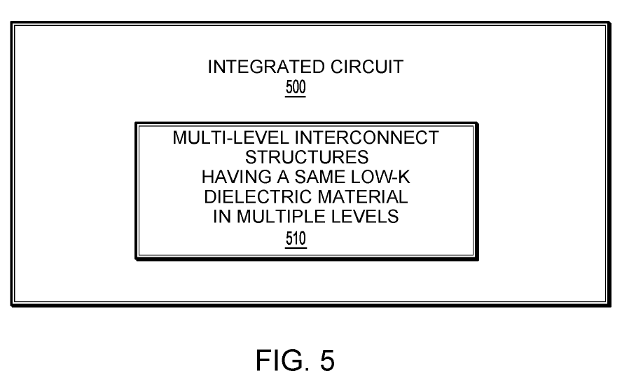

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor. FIG. 5 shows an example integrated circuit 500 which includes one or more multi-level interconnect structures 510 having a same low-k dielectric material (e.g., one of the novel high performance low-k dielectric materials described herein) in multiple (potentially all) levels.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. With respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
an active device region comprising one or more active devices; and
a multi-level interconnect structure comprising two or more levels of interconnects for the one or more active devices in the active device region;
wherein a silicon, carbon, nitrogen, oxygen and hydrogen (SiCNOH) dielectric material surrounds the interconnects in at least two of the two or more levels.

2. The semiconductor structure of claim 1, wherein the active device region comprises a front-end-of-line region and the multi-level interconnect structure comprises a back-end-of-line region.

3. The semiconductor structure of claim 2, further comprising a backside power delivery network comprising one or more power rail interconnections surrounded by the SiCNOH dielectric material.

4. The semiconductor structure of claim 1, wherein the SiCNOH dielectric material surrounds the interconnects in all of the two or more levels.

5. The semiconductor structure of claim 1, wherein the SiCNOH dielectric material provides an oxygen and metal diffusion barrier for the interconnects in the at least two of the two or more levels.

6. The semiconductor structure of claim 1, wherein a dielectric constant value of the SiCNOH dielectric material is less than or equal to 3.3.

7. The semiconductor structure of claim 1, wherein the interconnects in the at least two of the two or more levels comprise copper or aluminum.

8. The semiconductor structure of claim 1, wherein the SiCNOH dielectric material comprises a porous SiCNOH dielectric material.

9. The semiconductor structure of claim 1, wherein the SiCNOH dielectric material comprises greater than 50 atomic percentage carbon, less than 10 atomic percentage nitrogen and less than 10 atomic percentage oxygen.

10. The semiconductor structure of claim 9, wherein the SiCNOH dielectric material comprises 20-35 atomic percentage silicon and 10-20 atomic percentage hydrogen.

11. The semiconductor structure of claim 10, wherein the SiCNOH dielectric material comprises 3-8 atomic percentage nitrogen and 1-8 atomic percentage oxygen.

12. A semiconductor structure comprising:
a front-end-of-line region comprising one or more active devices; and
a back-end-of-line region comprising metal interconnects for the one or more active devices, the metal interconnects being arranged in a hierarchy of two or more levels, a bottommost one of the two or more levels being adjacent the front-end-of-line region;
wherein a silicon, carbon, nitrogen, oxygen and hydrogen (SiCNOH) interlayer dielectric material surrounding the metal interconnects in at least two of the two or more levels.

13. The semiconductor structure of claim 12, wherein the SiCNOH interlayer dielectric material directly contacts the metal interconnects in the at least two of the two or more levels.

14. The semiconductor structure of claim 12, wherein the SiCNOH interlayer dielectric material surrounds the metal interconnects in all of the two or more levels.

15. The semiconductor structure of claim 12, wherein the at least two of the two or more levels includes an uppermost one of the two or more levels which utilizes copper or aluminum for the metal interconnects.

16. The semiconductor structure of claim 12, wherein the SiCNOH interlayer dielectric material comprises 20-35 atomic percentage silicon, greater than 50 atomic percentage carbon, less than 10 atomic percentage nitrogen, less than 10 atomic percentage oxygen and 10-20 atomic percentage hydrogen.

17. An integrated circuit comprising:
a semiconductor structure comprising:
an active device region comprising one or more active devices; and
a multi-level interconnect structure comprising two or more levels of interconnects for the one or more active devices in the active device region;
wherein a silicon, carbon, nitrogen, oxygen and hydrogen (SiCNOH) dielectric material surrounds the interconnects in at least two of the two or more levels of interconnects.

18. The integrated circuit of claim 17, wherein the SiCNOH dielectric material surrounds the interconnects in all of the two or more levels.

19. The integrated circuit of claim 17, wherein the interconnects in the at least two of the two or more levels comprise copper or aluminum.

20. The integrated circuit of claim 17, wherein the SiCNOH dielectric material comprises 20-35 atomic percentage silicon, greater than 50 atomic percentage carbon, less than 10 atomic percentage nitrogen, less than 10 atomic percentage oxygen and 10-20 atomic percentage hydrogen.
